(19) United States
(12) Patent Application Publication
(10) Pub. No.: US 2025/0232071 A1
(43) Pub. Date: Jul. 17, 2025

(54) DESIGN EXPLORER FOR COMPOSING PRODUCTS USING COMMON MODULAR SUBSYSTEMS AND COMPONENTS

(71) Applicant: Raytheon Company, Waltham, MA (US)

(72) Inventors: Joseph B. Lail, Tucson, AZ (US); Jeffrey D. Turpin, San Diego, CA (US); Grayson D. Ross, Oak Park, CA (US); Bobbi J. Young, Tucson, AZ (US); Jennifer Wendt, Tucson, AZ (US); Robert G. Genis, Jr., Tucson, AZ (US); Nicholas W. Barrett, Oro Valley, AZ (US); Francis F. Tiberio, Marana, AZ (US)

(21) Appl. No.: 17/934,821

(22) Filed: Sep. 23, 2022

(51) Int. Cl. G06F 30/12

(52) U.S. Cl. CPC G06F 30/12

(57) ABSTRACT

Initial information associated with a product to be designed is obtained, where at least some initial information identifies an intended application. Multiple features associated with the product are identified. For each feature, one or more feature options acceptable for use in the application are identified, and one or more components or subsystems associated with the acceptable option(s) are identified. At least some identified components or subsystems are reusable in multiple products. Feasible configurations are generated based on the identified components or subsystems. Each feasible configuration represents a potential design for the product and is acceptable for use in the application. One or more simulations or analyses associated with each feasible configuration are performed, where at least one simulation or analysis estimates performance of each feasible configuration. A user interface is generated that identifies one or more feasible configurations and results associated with the simulations or analyses or information based thereon.

### TECHNICAL FIELD

This disclosure is generally directed to automated design systems. More specifically, this disclosure is directed to a design explorer for composing products using common modular subsystems and components.

### BACKGROUND

Composability refers to the ability of an organization to rapidly develop new systems through the use of modular components and subsystems in order to meet the needs of at least one family of products. For example, in the defense industry, effectors refer to missiles, lasers, or other systems designed to achieve specified effects. Within a family of effector products, it may be possible to design multiple products using the same modular components and subsystems, such as sets of propulsion systems, guidance systems, and payloads. Ideally, the ability to reuse modular components and subsystems across multiple products (or even product families) can enable numerous products to be designed using the same components and subsystems, which can significantly reduce the time, effort, and cost associated with designing and manufacturing the products.

### SUMMARY

This disclosure relates to a design explorer for composing products using common modular subsystems and components.

In a first embodiment, a method includes obtaining, using at least one processing device, initial information associated with a product to be designed. At least some of the initial information identifies an intended application for the product to be designed. The method also includes identifying, using the at least one processing device, multiple features associated with the product to be designed based on the initial information. The method further includes identifying, using the at least one processing device and for each of the multiple features, one or more feature options that are acceptable for use in the intended application. The method also includes identifying, using the at least one processing device and for each of the multiple features, one or more components or subsystems that are associated with the one or more acceptable feature options for that feature. At least some of the identified components or subsystems are reusable in multiple products. The method further includes generating, using the at least one processing device, multiple feasible candidate product configurations based on the identified components or subsystems. Each feasible candidate product configuration represents a potential design for the product and is acceptable for use in the intended application. The method also includes performing, using the at least one processing device, one or more simulations or analyses associated with each of the feasible candidate product configurations. At least one of the one or more simulations or analyses estimates performance of each of the feasible candidate product configurations. In addition, the method includes generating, using the at least one processing device, a graphical user interface that identifies (i) one or more of the feasible candidate product configurations and (ii) one or more results associated with the one or more simulations or analyses or information based thereon.

In a second embodiment, an apparatus includes at least one processing device configured to obtain initial information associated with a product to be designed. At least some of the initial information identifies an intended application for the product to be designed. The at least one processing device is also configured to identify multiple features associated with the product to be designed based on the initial information. The at least one processing device is further configured to identify, for each of the multiple features, one or more feature options that are acceptable for use in the intended application. The at least one processing device is also configured to identify, for each of the multiple features, one or more components or subsystems that are associated with the one or more acceptable feature options for that feature. At least some of the identified components or subsystems are reusable in multiple products. The at least one processing device is further configured to generate multiple feasible candidate product configurations based on the identified components or subsystems. Each feasible candidate product configuration represents a potential design for the product and is acceptable for use in the intended application. The at least one processing device is also configured to perform one or more simulations or analyses associated with each of the feasible candidate product configurations. At least one of the one or more simulations or analyses estimates performance of each of the feasible candidate product configurations. In addition, the at least one processing device is configured to generate a graphical user interface that identifies (i) one or more of the feasible candidate product configurations and (ii) one or more results associated with the one or more simulations or analyses or information based thereon.

In a third embodiment, a non-transitory computer readable medium contains instructions that when executed cause at least one processor to obtain initial information associated with a product to be designed. At least some of the initial information identifies an intended application for the product to be designed. The medium also contains instructions that when executed cause the at least one processor to identify multiple features associated with the product to be designed based on the initial information. The medium further contains instructions that when executed cause the at least one processor to identify, for each of the multiple features, one or more feature options that are acceptable for use in the intended application. The medium also contains instructions that when executed cause the at least one processor to identify, for each of the multiple features, one or more components or subsystems that are associated with the one or more acceptable feature options for that feature. At least some of the identified components or subsystems are reusable in multiple products. The medium further contains instructions that when executed cause the at least one processor to generate multiple feasible candidate product configurations based on the identified components or subsystems. Each feasible candidate product configuration represents a potential design for the product and is acceptable for use in the intended application. The medium also contains instructions that when executed cause the at least one processor to perform one or more simulations or analyses associated with each of the feasible candidate product configurations. At least one of the one or more simulations or analyses estimates performance of each of the feasible candidate product configurations. In addition, the medium contains instructions that when executed cause the at least one processor to generate a graphical user interface that identifies (i) one or more of the feasible candidate product configurations and (ii) one or more results associated with the one or more simulations or analyses or information based thereon.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIG. 1 illustrates an example system supporting a design explorer for composing products using common modular subsystems and components according to this disclosure;

FIG. 2 illustrates an example device supporting a design explorer for composing products using common modular subsystems and components according to this disclosure;

FIGS. 3A and 3B illustrate an example process supporting a design explorer for composing products using common modular subsystems and components according to this disclosure;

FIG. 4 illustrates an example network architecture supporting a design explorer for composing products using common modular subsystems and components according to this disclosure;

FIG. 5 illustrates an example functional architecture supporting a design explorer for composing products using common modular subsystems and components according to this disclosure;

FIG. 6 illustrates an example functional hierarchy supporting a design explorer for composing products using common modular subsystems and components according to this disclosure;

FIGS. 7 through 16 illustrate an example graphical user interface supporting a design explorer for composing products using common modular subsystems and components according to this disclosure; and

FIG. 17 illustrates an example method for using a design explorer for composing products using common modular subsystems and components according to this disclosure.

### DETAILED DESCRIPTION

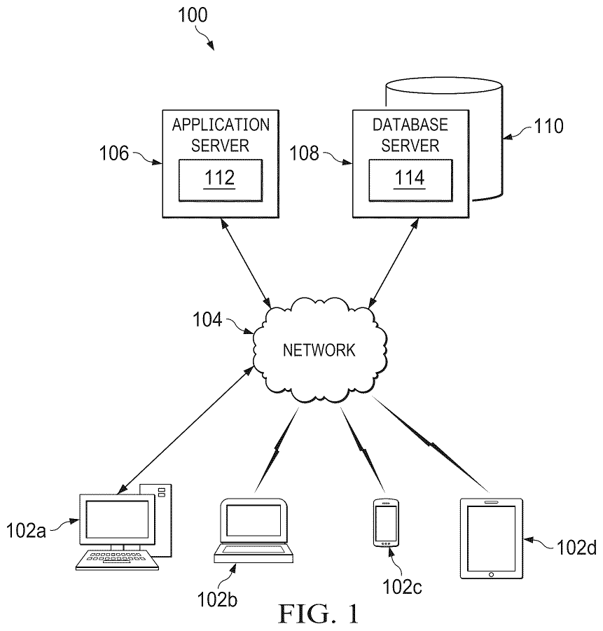

FIGS. 1 through 17, described below, and the various embodiments used to describe the principles of the present invention in this patent document are by way of illustration only and should not be construed in any way to limit the scope of the invention. Those skilled in the art will understand that the principles of the present invention may be implemented in any type of suitably arranged device or system.

As noted above, composability refers to the ability of an organization to rapidly develop new systems through the use of modular components and subsystems in order to meet the needs of at least one family of products. For example, in the defense industry, effectors refer to missiles, lasers, or other systems designed to achieve specified effects. Within a family of effector products, it may be possible to design multiple products using the same modular components and subsystems, such as sets of propulsion systems, guidance systems, and payloads. Ideally, the ability to reuse modular components and subsystems across multiple products (or even product families) can enable numerous products to be designed using the same components and subsystems, which can significantly reduce the time, effort, and cost associated with designing and manufacturing the products.

Unfortunately, it is often possible for hundreds or thousands of component and subsystem combinations to exist, and it can be very time-consuming to identify valid combinations of components and subsystems and then analyze each combination in order to determine whether that combination satisfies design criteria for a specific application. While there are tools that can be used to automatically identify all valid product configurations that might be designed using a specified collection of components and subsystems, these tools lack an ability to analyze the valid product configurations. Moreover, it is often difficult to incorporate additional components and subsystems into a design process for consideration during the generation of potential product configurations.

This disclosure provides a design explorer for composing products using common modular subsystems and components. As described in more detail below, the design explorer includes or supports a graphical user interface that allows users to define one or more characteristics of an intended application, and feasible candidate product configurations can be identified for the intended application using the characteristic(s) and presented to the users for review. Services can be supported to help the users make educated selections of subsystems and components for use based on various factors (such as schedule, performance, cost, etc.). Simulations or other analyses of the feasible candidate product configurations can also be performed, and aspects of selected feasible candidate product configurations (including the results of the simulations) can be compared across multiple dimensions. In some cases, the design parameters of feasible candidate product configurations can be automatically extracted and input into suitable simulation environments. The generation of feasible candidate product configurations can occur iteratively based on the simulations or other analyses or based on additional user selections, ideally until at least one solution can be found that identifies a feasible candidate product configuration that is suitable for use in the intended application and that satisfies one or more criteria.

Overall, the design explorer makes it much easier for users to identify potential product configurations, run simulations or other analyses involving the potential product configurations, and compare the potential product configurations. With many design option choices, the design explorer can significantly reduce user efforts by narrowing down the number of feasible design permutations. The comparison capability enables evaluation of the potential product configurations, and tools allow teams to more quickly evaluate trade-offs between different potential product configurations in order to aide in the decision-making process. The integration of simulation capabilities and other analysis tools allows users to visually navigate potential product configurations while providing estimated performance and other data related to the potential product configurations. These functions can help to accelerate product development by reducing the number of possible design configurations to only those configurations that are practical for a given application. This can also help to remove individual biases and improve the consistency and repeatability of the evaluations of the potential product configurations. Moreover, this approach can allow for easier integration of additional components and subsystems into the design process for consideration during the generation of potential design configurations. In some cases, a scalable cloud-based infrastructure may be used to support the design explorer, which can help make the design explorer more scalable, reliable, and portable.

Note that while the functionality of the design explorer is often described in this patent document as being used to design effectors, the design explorer may be used to support the design of any suitable products using collections of components and subsystems associated with at least one family of products. Other examples of products that might be designed using the design explorer may include satellites, radar systems, and automotive vehicles. In general, this disclosure is not limited to the design of any particular type of product.

FIG. 1 illustrates an example system 100 supporting a design explorer for composing products using common modular subsystems and components according to this disclosure. As shown in FIG. 1, the system 100 includes multiple user devices 102a-102d, at least one network 104, at least one application server 106, and at least one database server 108 associated with at least one database 110. Note, however, that other combinations and arrangements of components may also be used here.

In this example, each user device 102a-102d is coupled to or communicates over the network 104. Communications between each user device 102a-102d and a network 104 may occur in any suitable manner, such as via a wired or wireless connection. Each user device 102a-102d represents any suitable device or system used by at least one user to provide information to the application server 106 or database server 108 or to receive information from the application server 106 or database server 108. Any suitable number(s) and type(s) of user devices 102a-102d may be used in the system 100. In this particular example, the user device 102a represents a desktop computer, the user device 102b represents a laptop computer, the user device 102c represents a smartphone, and the user device 102d represents a tablet computer. However, any other or additional types of user devices may be used in the system 100. Each user device 102a-102d includes any suitable structure configured to transmit and/or receive information.

The network 104 facilitates communication between various components of the system 100. For example, the network 104 may communicate Internet Protocol (IP) packets, frame relay frames, Asynchronous Transfer Mode (ATM) cells, or other suitable information between network addresses. The network 104 may include one or more local area networks (LANs), metropolitan area networks (MANs), wide area networks (WANs), all or a portion of a global network such as the Internet, or any other communication system or systems at one or more locations. The network 104 may also operate according to any appropriate communication protocol or protocols.

The application server 106 is coupled to the network 104 and is coupled to or otherwise communicates with the database server 108. The application server 106 supports the use of a design explorer for composing products using common modular subsystems and components. For example, the application server 106 may execute one or more applications 112 supporting the functions of the design explorer described below. Among other things, the one or more applications 112 may use various information 114 stored in the database 110 to perform one or more functions of the design explorer. The database server 108 operates to store and facilitate retrieval of various information 114 used, generated, or collected by the application server 106 and the user devices 102a-102d in the database 110. For instance, the database server 108 may store various information 114 in relational database tables or other data structures in the database 110. Note, however, that the database server 108 may be used within the application server 106 to store the information 114, in which case the application server 106 may store the information 114 itself.

Although FIG. 1 illustrates one example of a system 100 supporting a design explorer for composing products using common modular subsystems and components, various changes may be made to FIG. 1. For example, the system 100 may include any number of user devices 102a-102d, networks 104, application servers 106, database servers 108, and databases 110. Also, these components may be located in any suitable locations and might be distributed over a large area. In addition, while FIG. 1 illustrates one example operational environment in which a design explorer may be used, this functionality may be used in any other suitable system.

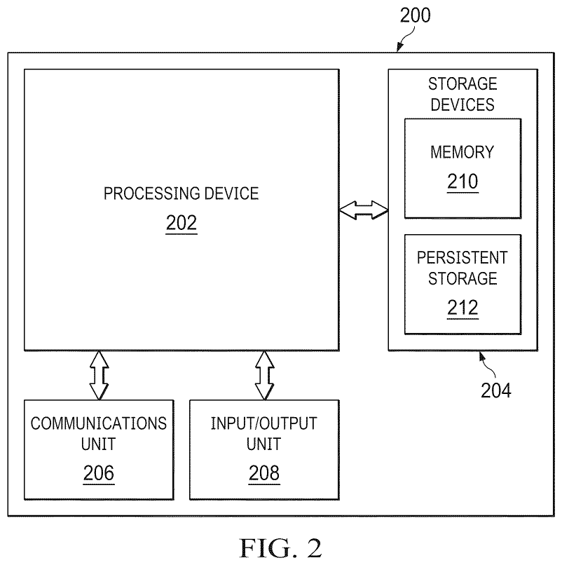

FIG. 2 illustrates an example device 200 supporting a design explorer for composing products using common modular subsystems and components according to this disclosure. One or more instances of the device 200 may, for example, be used to at least partially implement the functionality of the one or more applications 112 of FIG. 1. However, the functionality of the one or more applications 112 may be implemented in any other suitable manner. In some embodiments, the device 200 shown in FIG. 2 may form at least part of a user device 102a-102d, application server 106, or database server 108 in FIG. 1. However, each of these components may be implemented in any other suitable manner.

As shown in FIG. 2, the device 200 denotes a computing device or system that includes at least one processing device 202, at least one storage device 204, at least one communications unit 206, and at least one input/output (I/O) unit 208. The processing device 202 may execute instructions that can be loaded into a memory 210. The processing device 202 includes any suitable number(s) and type(s) of processors or other processing devices in any suitable arrangement. Example types of processing devices 202 include one or more microprocessors, microcontrollers, digital signal processors (DSPs), application specific integrated circuits (ASICs), field programmable gate arrays (FPGAs), or discrete circuitry.

The memory 210 and a persistent storage 212 are examples of storage devices 204, which represent any structure(s) capable of storing and facilitating retrieval of information (such as data, program code, and/or other suitable information on a temporary or permanent basis). The memory 210 may represent a random access memory or any other suitable volatile or non-volatile storage device(s). The persistent storage 212 may contain one or more components or devices supporting longer-term storage of data, such as a read only memory, hard drive, Flash memory, or optical disc.

The communications unit 206 supports communications with other systems or devices. For example, the communications unit 206 can include a network interface card or a wireless transceiver facilitating communications over a wired or wireless network. The communications unit 206 may support communications through any suitable physical or wireless communication link(s). As a particular example, the communications unit 206 may support communication over the network(s) 104 of FIG. 1.

The I/O unit 208 allows for input and output of data. For example, the I/O unit 208 may provide a connection for user input through a keyboard, mouse, keypad, touchscreen, or other suitable input device. The I/O unit 208 may also send output to a display, printer, or other suitable output device. Note, however, that the I/O unit 208 may be omitted if the device 200 does not require local I/O, such as when the device 200 represents a server or other device that can be accessed remotely.

In some embodiments, instructions executed by the processing device 202 include instructions that implement the functionality of the one or more applications 112. Thus, for example, the instructions executed by the processing device 202 may be used to implement the design explorer described in more detail below. The design explorer can be used by one or more users (such as via the user devices 102a-102d) to define products using modular subsystems and components.

Although FIG. 2 illustrates one example of a device 200 supporting a design explorer for composing products using common modular subsystems and components, various changes may be made to FIG. 2. For example, computing and communication devices and systems come in a wide variety of configurations, and FIG. 2 does not limit this disclosure to any particular computing or communication device or system.

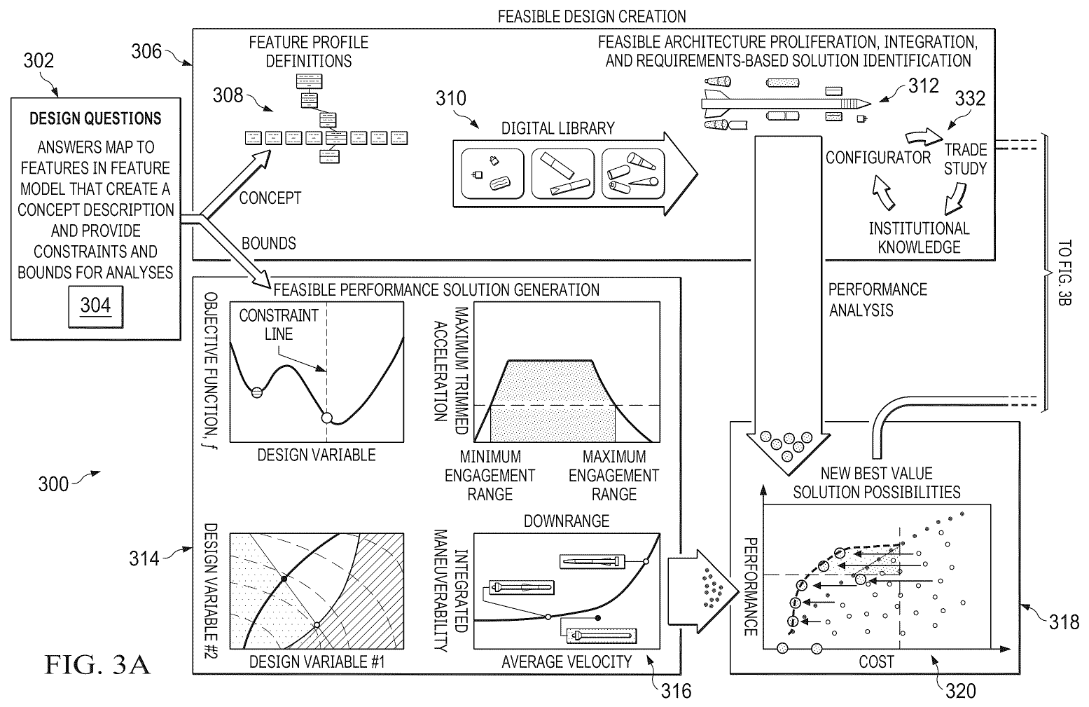

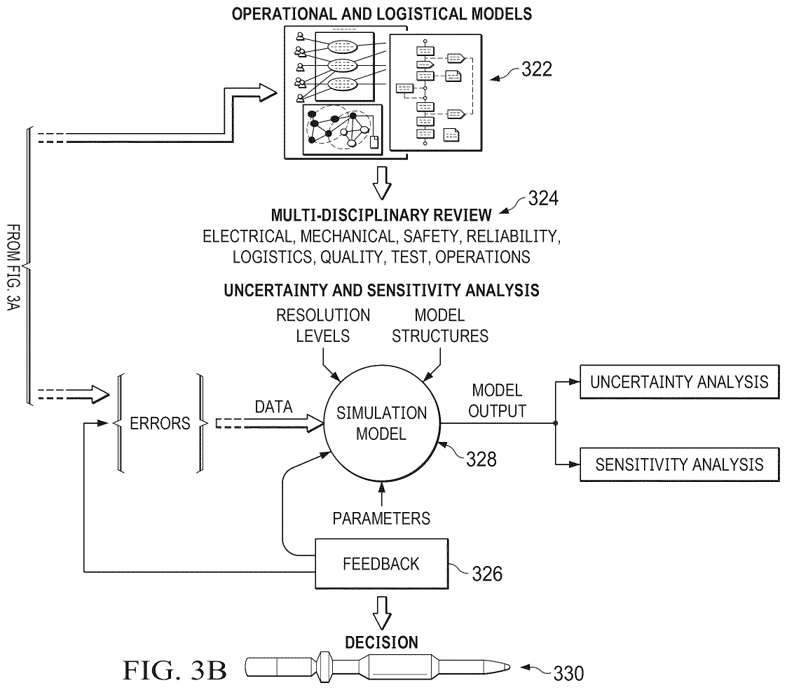

FIGS. 3A and 3B illustrate an example process 300 supporting a design explorer for composing products using common modular subsystems and components according to this disclosure. For ease of explanation, the process 300 shown in FIGS. 3A and 3B is described as being performed using components in the system 100 of FIG. 1, at least one of which may be implemented using the device 200 of FIG. 2. However, the process 300 shown in FIGS. 3A and 3B may be performed by any suitable device(s) and in any suitable system(s).

As shown in FIGS. 3A and 3B, the process 300 generally starts with obtaining a collection of answers to a set of design questions 302. The design questions 302 may be designed to elicit information from one or more users about an intended application for a product. For instance, when being used to design a defense-related effector, the design questions 302 may be used to identify how the effector to be designed will be used and the intended type of target for the effector to be designed. Answers to the design questions 302 can be provided to a feature model 304, such as a machine learning model or other logic, that can map the answers to the design questions 302 to features defined by the feature model 304. The feature model 304 can be used to represent or model all of the features that are achievable using subsystems and components available for use in designing products. Mapping the answers to the design questions 302 to various features defined by the feature model 304 allows the feature model 304 to be used to identify initial information about the product(s) being designed. Among other things, the initial information can include concept information indicating the general features to be supported for the intended application and bounds or limits for the product to be designed based on the intended application.

The concept information indicating the general features to be supported is provided to a feasible design creation function 306, which generally operates to identify feasible designs for a product based on the answers to the design questions 302. For example, the feasible design creation function 306 can have access to various feature profile definitions 308, each of which can define different feature options that are available or usable for a specific product feature. For instance, a feature profile definition 308 related to launching mechanisms available for use in designing a specific effector may identify various potential launching mechanisms that are available. One or more outputs from the feature model 304 may be used to identify that specific launching mechanisms from among the potential launching mechanisms are or are not feasible for use given the intended application. As a particular example, this feature profile definition 308 may identify that various launching pad, vertical launch, underwater launch, rail launch, eject launch, rocket launch, boat launch, and torpedo tube launch mechanisms are available for use. Each type of launch mechanism can be associated with one or more specific components or subsystems supporting that type of launch mechanism. However, given the answers to the design questions 302, only the rail launch and eject launch mechanisms might be suitable for use in the intended application. As a result, the feasible design creation function 306 can use the feature profile definition 308 to identify one or more specific components or subsystems supporting one or more potential types of launch mechanisms that could be used for the intended application and can disregard one or more specific components or subsystems that cannot be used for the intended application. This can be repeated for multiple (and possibly numerous) features for the product being designed in order to identify the viable feature options for each feature.

The feasible design creation function 306 also has access to a digital library 310, which can identify all of the components and subsystems that might be used to create designs for products. For example, the digital library 310 may include information associated with various categories of components and subsystems and, for each category, information associated with the components and subsystems within that category. As a particular example, effectors may be associated with a number of component/subsystem categories, such as seekers, mission systems, guidance electronics, navigation systems, payloads, communication systems, power systems, propulsion systems, and precision control systems. The digital library 310 can identify one or more components and subsystems that might be used in each of these various component/subsystem categories when designing products.

The feasible design creation function 306 uses the components and subsystems that are identified using the feature profile definitions 308 and the digital library 310 to create one or more feasible candidate product configurations 312. Here, the components and subsystems that are identified using the feature profile definitions 308 and the digital library 310 represent components and subsystems that are suitable for use in the intended application based on the answers to the design questions 302. As a result, each feasible candidate product configuration 312 is also initially identified as being suitable for use in the intended application. For instance, in the example above, the feature profile definition 308 for the launch mechanism may be used to identify that rail launch and eject launch mechanisms are suitable for an intended application. The feasible design creation function 306 can access the digital library 310 in order to identify all of the rail launch and eject launch components or subsystems that are available for use. The feasible design creation function 306 may perform similar functions for each component/subsystem category (or a subset thereof) in order to identify all of the components and subsystems that may be used to design a particular product. Because it is known here which components and subsystems are suitable for use in a given application (via the feature profile definitions 308) and which specific components and subsystems are available for use (via the digital library 310), the candidate product configurations 312 generated by the feasible design creation function 306 are known to be feasible, meaning that the candidate product configurations 312 could potentially be suitable for use in the given application (since the candidate product configurations 312 are designed using components and subsystems suitable for that given application). Thus, for instance, there may be no need for a user to review a large number of potential product configurations 312 that cannot be used in the given application. In some cases, one or more of the feasible product configurations 312 can be designed based on input from at least one user, such as when the user selects different components and subsystems that are identified are usable in the intended application.

The information related to the bounds or limits for the product to be designed is provided to a feasible performance solution generation function 314, which generally operates to estimate the feasible performance that can be expected for potential product configurations based on the answers to the design questions 302. For example, the feasible performance solution generation function 314 may identify multiple performance characteristics 316 that could be achieved based on the identified features of the product to be designed as determined using the feature model 304. As particular examples, the performance characteristics 316 for an effector in the form of a missile may include performance characteristics 316 related to factors such as expected maneuverability, velocity, and acceleration of the missile and tradeoffs between or involving certain design parameters of the missile.

The candidate product configurations 312 and the performance characteristics 316 are provided to a performance analysis function 318, which generally operates to analyze the candidate product configurations 312 and the performance characteristics 316 and generate performance analysis results 320. The performance analysis results 320 can include various results related to the predicted performance of the candidate product configurations 312. For example, the performance analysis results 320 may include results indicating the estimated performance of the candidate product configurations 312 against the estimated costs of the candidate product configurations 312. These types of performance analysis results 320 can allow users to determine where an acceptable level of performance is obtained relative to the costs of the candidate product configurations 312. This allows the performance analysis function 318 to be used to identify the best potential candidate product configurations 312 in terms of performance and cost (although other or additional factors may also be considered here).

The feasible candidate product configurations 312 (or possibly only the best potential candidate product configurations 312) are subjected to various simulations or other analyses. For example, one or more operational and logical models 322 can be applied to one or more candidate product configurations 312. Each model 322 may be used to analyze one or more aspects of the candidate product configuration 312 under analysis. In this example, the model 322 can be used to perform a multiple-disciplinary review 324 of each candidate product configuration 312 under analysis, such as by analyzing each candidate product configuration 312 in terms of estimated electrical, mechanical, safety, reliability, logistical, quality, testing, and operational behaviors of the candidate product configuration 312. As particular examples, the model 322 may be used to determine whether a total electrical power usage of all components/subsystems in a candidate product configuration 312 is within an acceptable level compared to a power supply for the candidate product configuration 312 or whether a combined weight of all components/subsystems of the candidate product configuration 312 is within a specified limit.

One or more uncertainty and sensitivity analyses 326 may also be performed for one or more candidate product configurations 312, where each analysis 326 can involve the use of at least one simulation model 328. Each uncertainty and sensitivity analysis 326 can analyze the uncertainty of variables used in the analysis of a candidate product configuration 312 (uncertainty analysis) and how the total uncertainty can be allocated to different sources (sensitivity analysis). The same simulation model 328 or different simulation models 328 may support the use of different resolutions and model structures to perform these analyses, and parameter values used during these analyses can be varied as needed to support the uncertainty and sensitivity analyses. Feedback based on the uncertainty and sensitivity analyses can also be provided and used to support modifications of the input data or model parameters used for the analyses. In general, the uncertainty and sensitivity analyses 326 can be used to perform any desired analyses related to the design, performance, or other characteristic(s) of one or more candidate product configurations 312.

In some embodiments, various analyses described above as being performed within the process 300 can support the use of one or more trade studies. Trade studies generally involve performing analytical techniques for evaluating product/system designs. Among other things, trade studies allow for the identification of expected behaviors or other characteristics of candidate product configurations 312 so that one or more of the candidate product configurations 312 can be selected. Thus, users are able to review estimated or expected characteristics of the candidate product configurations 312 being analyzed in order to select which candidate product configuration(s) 312 might be best for the intended application. In some cases, there may be multiple types of trade studies supported, such as “business” trade studies and “engineering” trade studies. Business trade studies can focus on factors such as costs, delivery times, and other business-related features of the candidate product configurations 312. Engineering trade studies can focus on factors such as comparisons of different selected components/subsystems and different combinations of selected components/subsystems, such as achievable results associated with the candidate product configurations 312 (like the expected accuracy of different effector designs).

The results of the various trade studies or other analyses may be used to perform a final selection of a specific candidate product configuration 312, which can be used as a final product configuration 330 for the product being designed. The final product configuration 330 is ideally suitable for use in the intended application as defined by the answers to the design questions 302. Moreover, the final product configuration 330 ideally achieves suitable performance for the intended application at an acceptable cost. In addition, the final product configuration 330 ideally achieves satisfactory analysis results using the operational and logical model(s) 322 and the simulation model(s) 328. Note that if a final product configuration 330 satisfying these various criteria cannot be identified, one or more users may modify answers to the design questions 302 or take other actions that can result in additional candidate product configurations 312 being identified and analyzed. At least part of this iterative ability is shown as an iterative subprocess 332 in FIG. 3A. As shown here, the iterative subprocess 332 can involve the generation of candidate product configurations 312 via a configurator, the analysis of the candidate product configurations 312 using trade studies or other analyses, and the application of institutional or user knowledge based on the trade studies or other analyses to update existing candidate product configurations 312 or generate new candidate product configurations 312. The ability to iteratively modify product configurations can enable faster convergence to feasible product configurations that might be acceptable to the users.

It should be noted that the functions shown in or described with respect to FIGS. 3A and 3B can be implemented in at least one application server 106 or other device(s) in any suitable manner. For example, in some embodiments, at least some of the functions shown in or described with respect to FIGS. 3A and 3B can be implemented or supported using one or more software applications or other software instructions that are executed by the processing device(s) 202 of the at least one application server 106 or other device(s). In other embodiments, at least some of the functions shown in or described with respect to FIGS. 3A and 3B can be implemented or supported using dedicated hardware components. In general, the functions shown in or described with respect to FIGS. 3A and 3B can be performed using any suitable hardware or any suitable combination of hardware and software/firmware instructions.

Although FIGS. 3A and 3B illustrate one example of a process 300 supporting a design explorer for composing products using common modular subsystems and components, various changes may be made to FIGS. 3A and 3B. For example, components can be added, omitted, combined, further subdivided, replicated, or placed in any other suitable configuration in the process 300 according to particular needs.

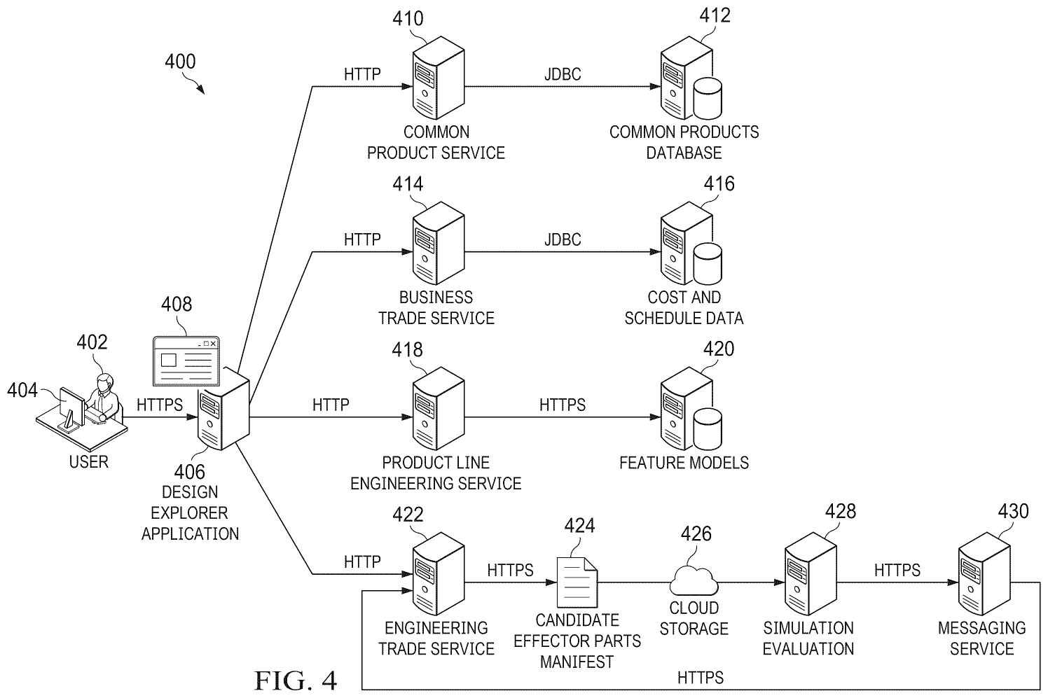

FIG. 4 illustrates an example network architecture 400 supporting a design explorer for composing products using common modular subsystems and components according to this disclosure. For ease of explanation, the network architecture 400 shown in FIG. 4 is described as being implemented using components in the system 100 of FIG. 1, at least one of which may be implemented using the device 200 of FIG. 2 and which may be used to implement the process 300 of FIGS. 3A and 3B. However, the network architecture 400 shown in FIG. 4 may be performed by any suitable device(s) and in any suitable system(s) and may be used to perform any suitable process(es).

As shown in FIG. 4, the network architecture 400 supports interactions with one or more users 402, which may interact with components of the network architecture 400 via one or more user devices 404 (such as any of the user devices 102a-102d). A computing system 406 (such as one or more application servers 106) executes a design explorer application, which may be implemented using one or more applications 112 executed by the computing system 406. The design explorer application can be used to implement at least part of the process 300 described above and various features described below. The design explorer application includes or supports at least one graphical user interface 408 to allow for interactions involving the user(s) 402. One specific example of a graphical user interface 408 that may be used here is described below.

In this example, the computing system 406 executing the design explorer application can interact with a number of additional computing systems (each of which may be implemented using one or more application servers 106). Various ones of these additional computing systems may interact with one or more databases and one or more database servers (which may be implemented using one or more database servers 108 and one or more databases 110). For example, a computing system 410 can be used to provide a common product service, which can be used to identify and manage common components and subsystems that are available for use in designing different products. Information about the common components and subsystems can be stored in a database 412. As a particular example, the computing system 410 may be used to identify the common components and subsystems and to store information about the components and subsystems in the digital library 310, which can be stored in the database 412. A computing system 414 can be used to provide a business trade service, which can be used to perform one or more business trade studies. For instance, information about costs and production schedules can be stored in a database 416, and this information can be used to perform business trade studies. A computing system 418 can be used to provide a product line engineering service, which can be used to apply one or more feature models 304 stored in a database 420. For example, the product line engineering service can apply a feature model 304 to a user's answers to design questions 302 in order to identify features of a product being designed for the user.

In addition, a computing system 422 can be used to implement an engineering trade service, which can be used to perform one or more engineering trade studies. For example, the engineering trade service can be used to identify parts manifests 424 for candidate product configurations 312. The parts manifests 424 can identify different combinations of components and subsystems that (based on output from the product line engineering service and the business trade service) would be usable given an intended application as defined by the user's answers to the design questions 302. The parts manifests 424 can be stored, such as in a cloud storage 426 or other suitable location(s). A computing system 428 can be used to perform simulations (such as those using one or more simulation models 328) for the identified candidate product configurations 312 using the parts manifests 424. Results of the simulations may be provided to a computing system 430 that implements a messaging service or other service that can be used to provide simulation results back to the computing system 422 or other suitable destination(s).

Using this type of approach, the design explorer application executed by the computing system 406 is able to use a distributed architecture (such as a hybrid cloud architecture) to aggregate and evaluate common feature-based designs for effectors or other products. The designs here can be selected based on cost and schedule data (such as from an enterprise resource planning systems), performance data (such as from a simulator), and a common component/subsystem library.

Note that the use of specific communication protocols is shown in FIG. 4, such as the Hypertext Transfer Protocol (HTTP), HTTP-Secure (HTTPS), and JAVA Database Connectivity (JDBC) protocols. However, the use of these specific communication protocols is for illustration only, and any suitable communication protocol or protocols may be used between components of the network architecture 400.

Although FIG. 4 illustrates one example of a network architecture 400 supporting a design explorer for composing products using common modular subsystems and components, various changes may be made to FIG. 4. For example, components can be added, omitted, combined, further subdivided, replicated, or placed in any other suitable configuration in the network architecture 400 according to particular needs. As a particular example, functions may be performed by fewer or more computing systems than described above, and data may be stored by fewer or more databases than described above.

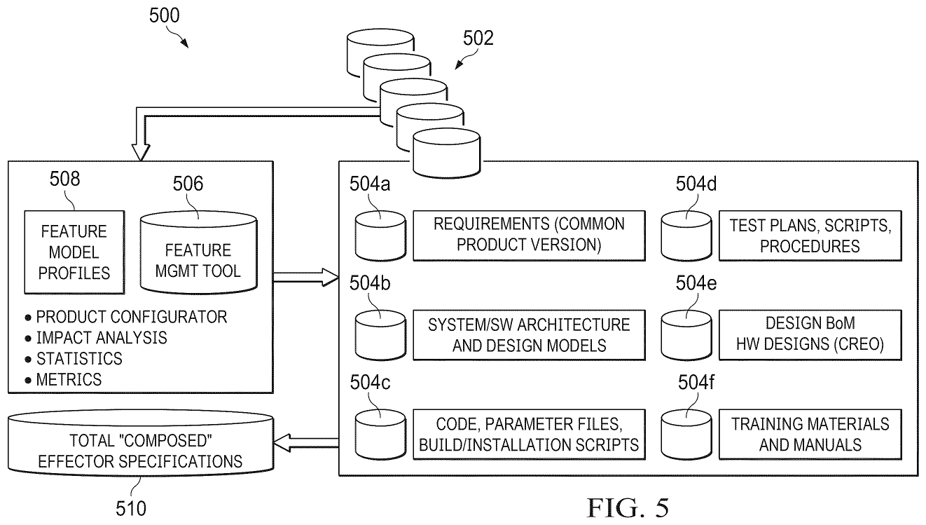

FIG. 5 illustrates an example functional architecture 500 supporting a design explorer for composing products using common modular subsystems and components according to this disclosure. For ease of explanation, the functional architecture 500 shown in FIG. 5 is described as being implemented using components in the system 100 of FIG. 1, at least one of which may be implemented using the device 200 of FIG. 2 and which may be used to implement the process 300 of FIGS. 3A and 3B and the network architecture 400 of FIG. 4. However, the functional architecture 500 shown in FIG. 5 may be implemented using any suitable device(s) and in any suitable system(s) or network architecture(s) and may be used to perform any suitable process(es).

As shown in FIG. 5, the functional architecture 500 can be used here to support the integration of design requirements into the development of candidate product configurations 312. This type of functionality may, for example, be used by the engineering trade service provided by the computing system 422. As can be seen here, the functional architecture 500 has access to one or more data stores 502 that store data related to engineering requirements, such as engineering requirements related to different projects or programs for which products may be designed. The data stores 502 may include any suitable source(s) of engineering requirements, such as one or more engineering requirements management data sources (like DOORS software from IBM).

In this particular example, the data stores 502 may be used to store at least one database 504a related to program requirements, which can possibly be expressed using common nomenclature across different products. The data stores 502 may also be used to store at least one database 504b containing system/software architecture and design models related to software associated with the projects or programs and at least one database 504c containing code, parameter files, and build/installation scripts associated with the projects or programs. The data stores 502 may further be used to store at least one database 504d containing test plans, scripts, and procedures associated with the projects or programs and at least one database 504e containing design bills of materials (BoMs) and hardware designs associated with the projects or programs. In some cases, the hardware designs may be defined or captured using Creo Parametric software from PTC. In addition, the data stores 502 may be used to store at least one database 504f containing training materials and manuals associated with the projects or programs.

A feature management tool 506 can be used to identify features and generate various information 508 used by other components of the system 100, process 300, or network architecture 400. For example, the feature management tool 506 can be used to identify common features across multiple programs or projects and generate profiles (such as feature profile definitions 308) based on available feature options associated with the features. This information 508 can be used by various functions, such as a product configurator (which identifies the feasible candidate product configurations 312) and various types of analysis functions. Once a feasible candidate product configuration 312 is identified, information relevant to that feasible candidate product configuration 312 can be identified in the data stores 502 and used to produce a specification 510 for that feasible candidate product configuration 312.

Although FIG. 5 illustrates one example of a functional architecture 500 supporting a design explorer for composing products using common modular subsystems and components, various changes may be made to FIG. 5. For example, components can be added, omitted, combined, further subdivided, replicated, or placed in any other suitable configuration in the functional architecture 500 according to particular needs.

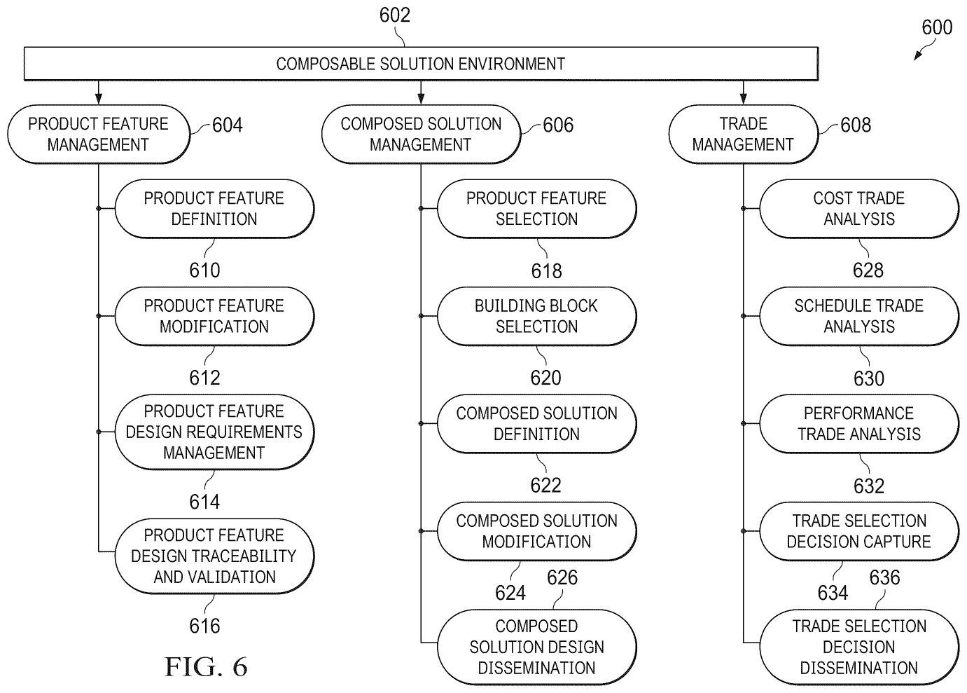

FIG. 6 illustrates an example functional hierarchy 600 supporting a design explorer for composing products using common modular subsystems and components according to this disclosure. For ease of explanation, the functional hierarchy 600 shown in FIG. 6 is described as being supported by components in the system 100 of FIG. 1, at least one of which may be implemented using the device 200 of FIG. 2 and which may be used to implement the process 300 of FIGS. 3A and 3B, the network architecture 400 of FIG. 4, and the functional architecture 500 of FIG. 5. However, the functional hierarchy 600 shown in FIG. 6 may be supported by any suitable device(s) and in any suitable system(s), network architecture(s), or functional architecture(s) and may be used to perform any suitable process(es).

As shown in FIG. 6, the functional hierarchy 600 here generally includes a number of functions used within a composability solution environment 602, which may represent the overall functionality of the design explorer. The functions of the composability solution environment 602 may be roughly divided into three classifications of functions, namely product feature management functions 604, composed solution management functions 606, and trade management functions 608. Note, however, that the composability solution environment 602 can support other functions within or outside these three classifications as needed or desired.

The product feature management functions 604 generally represent functions that support the usage of product features. For example, the product feature management functions 604 can include a product feature definition function 610, which can be used to define the specific features that are supported within the design explorer. These are the features that may, for instance, be identified by the feature model 304. The product feature management functions 604 can also include a product feature modification function 612, which can be used to alter or remove previously-defined features within the design explorer. The product feature management functions 604 can further include a product feature design requirements management function 614, which can be used to define one or more specific requirements associated with each feature supported within the design explorer. These specific requirements can control when those features may be selected for use with products being designed. This information may, for instance, be used to create the feature profile definitions 308. In addition, the product feature management functions 604 can include a product feature design traceability and validation function 616, which can be used to track changes made to features supported within the design explorer and validate current features used within the design explorer. The product feature management functions 604 can be implemented in any suitable manner, such as by using the GEARS software package from BIGLEVER SOFTWARE, INC.

The composed solution management functions 606 generally represent functions that support the definition and management of candidate product configurations 312. For example, the composed solution management functions 606 may include a product feature selection function 618, which can be used to select which features are associated with a product being designed. The composed solution management functions 606 may also include a building block selection function 620, which can be used to identify the components and subsystems that are suitable for use with the product being designed based on the features for that product. The composed solution management functions 606 may further include a composed solution definition function 622, which can select different combinations of the identified components and subsystems that are suitable for use with the product being designed to create different candidate product configurations 312. The composed solution management functions 606 may also include a composed solution management function 624, which can be used to alter or remove previously-defined candidate product configurations 312. In addition, the composed solution management functions 606 may include a composed solution design dissemination function 626, which can distribute one or more identified candidate product configurations 312 to analysis functions or other destination(s) for analysis or other use(s).

The trade management functions 608 generally represent functions that support the analysis of identified candidate product configurations 312. For example, the trade management functions 608 may include a cost trade analysis function 628, which may be used to perform one or more analyses related to costs of candidate product configurations 312. As a particular example, the costs of the various candidate product configurations 312 can be predicted over time given various available information, such as raw material or subcomponent stocks and fabrication costs. The trade management functions 608 may also include a schedule trade analysis function 630, which may be used to perform one or more analyses related to scheduling production of candidate product configurations 312. As a particular example, some candidate product configurations 312 may involve components that are in stock or simpler to fabricate or assemble/test compared to other candidate product configurations 312. The trade management functions 608 may further include a performance trade analysis function 632, which may be used to perform one or more analyses related to the simulated performances of candidate product configurations 312. As a particular example, the performances of the various candidate product configurations 312 can be predicted using simulations of physical environments where the candidate product configurations 312 might be used. The trade management functions 608 may also include a trade selection decision capture function 634, which can be used to identify the candidate product configuration 312 that is selected by at least one user. In addition, the trade management functions 608 may include a trade selection decision dissemination function 636, which can distribute information identifying or defining the selected candidate product configuration 312 to one or more suitable destinations for use. Note, however, that any other or additional analyses associated with any other or additional characteristics or perspectives of a system can be performed as part of the trade management functions 608.

Although FIG. 6 illustrates one example of a functional hierarchy 600 supporting a design explorer for composing products using common modular subsystems and components, various changes may be made to FIG. 6. For example, components can be added, omitted, combined, further subdivided, replicated, or placed in any other suitable configuration in the functional hierarchy 600 according to particular needs. Also, this division of functions is for illustration only, and other arrangements of these functions may be supported.

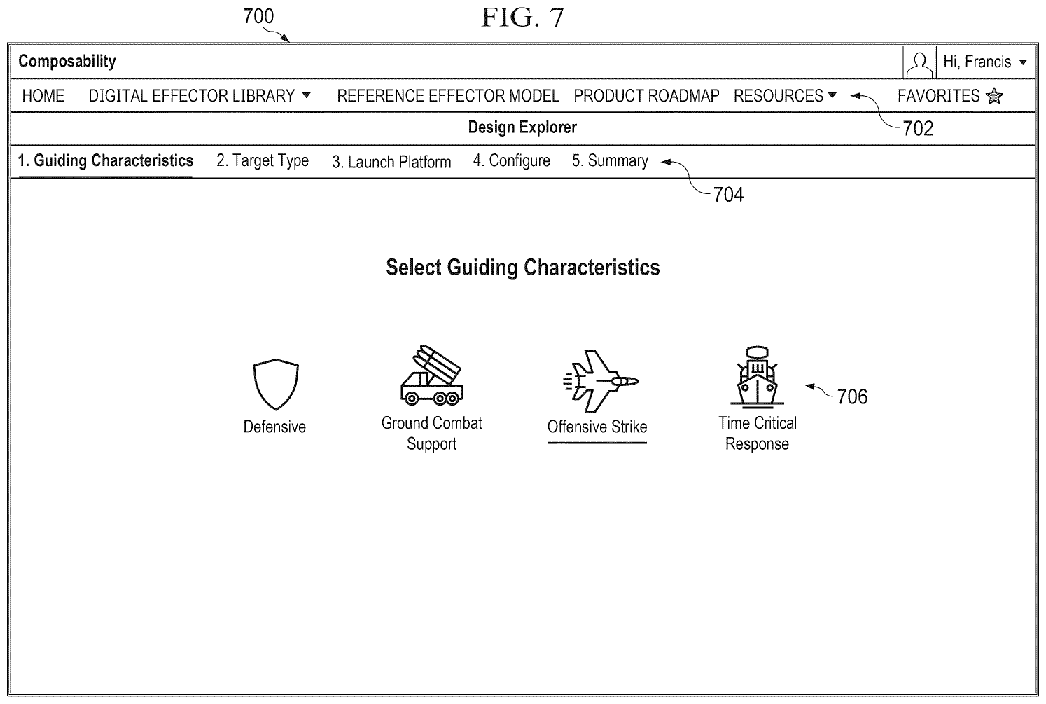

FIGS. 7 through 16 illustrate an example graphical user interface 700 supporting a design explorer for composing products using common modular subsystems and components according to this disclosure. For ease of explanation, the graphical user interface 700 is described as being provided by an application server 106 to one or more user devices 102a-102d in the system 100 of FIG. 1. In some cases, for instance, the graphical user interface 700 may represent the graphical user interface 408 of FIG. 4. However, the graphical user interface 700 shown in FIGS. 7 through 16 may be provided by or to any suitable device(s) and in any suitable system(s).

As shown in FIG. 7, the graphical user interface 700 includes a menu 702 that allows a user to invoke various functions. For example, the menu 702 may allow the user to return to a homepage of the graphical user interface 700, invoke various functions related to one or more effectors being designed, view a reference model for a generic effector, view one or more product roadmaps for one or more effectors, and access various resource information. In this example, the user has selected to use a design explorer application, such as via an appropriate selection in the menu 702. In this case, the graphical user interface 700 displays a set of tabs 704 that identify different steps or functions to be performed as part of the design explorer application.

As shown in FIGS. 7 through 9, the graphical user interface 700 collects the user's answers to various questions. These questions may, for example, represent the design questions 302 described above, which can be used to (among other things) identify the intended application for an effector being designed. In this particular example, the questions include a question 706 asking for an identification of the guiding characteristics for the effector being designed as shown in FIG. 7. Since effectors may have various designs and be used for various purposes, the guiding characteristics selected here can help to narrow down the possible candidate product configurations 312 to be generated, such as by limiting the possible features of the effector being designed. In this example, the question 706 involves the user selecting one of multiple clickable icons to indicate whether the effector being designed will be used for defensive purposes, for ground combat support, for offensive strike purposes, or for time-critical responses. Here, the user has indicated a desire to design an effector used for offensive strike purposes, which can represent one feature of the effector being designed.

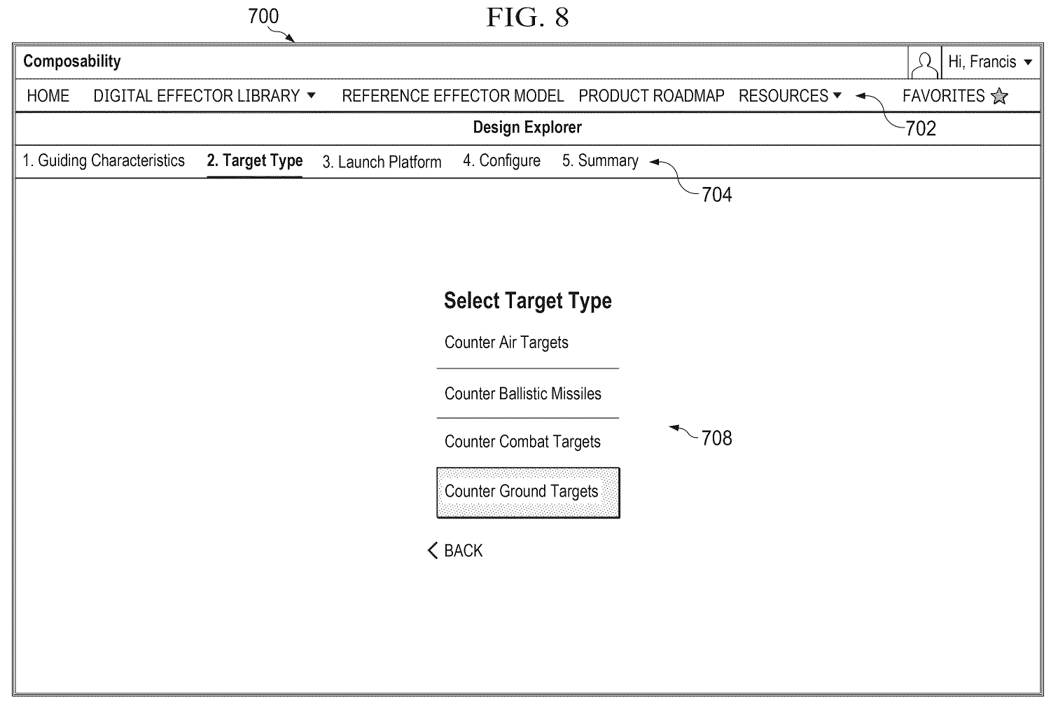

In this particular example, the questions also include a question 708 asking for an identification of the type of target against which the effector being designed might be used as shown in FIG. 8. In this example, the question 708 involves the user selecting one of multiple options in a list to indicate whether the effector being designed will be used to counter air targets, counter ballistic missiles, counter combat targets, or counter ground targets. Here, the user has indicated a desire to design an effector to counter ground targets, which can represent another feature of the effector being designed.

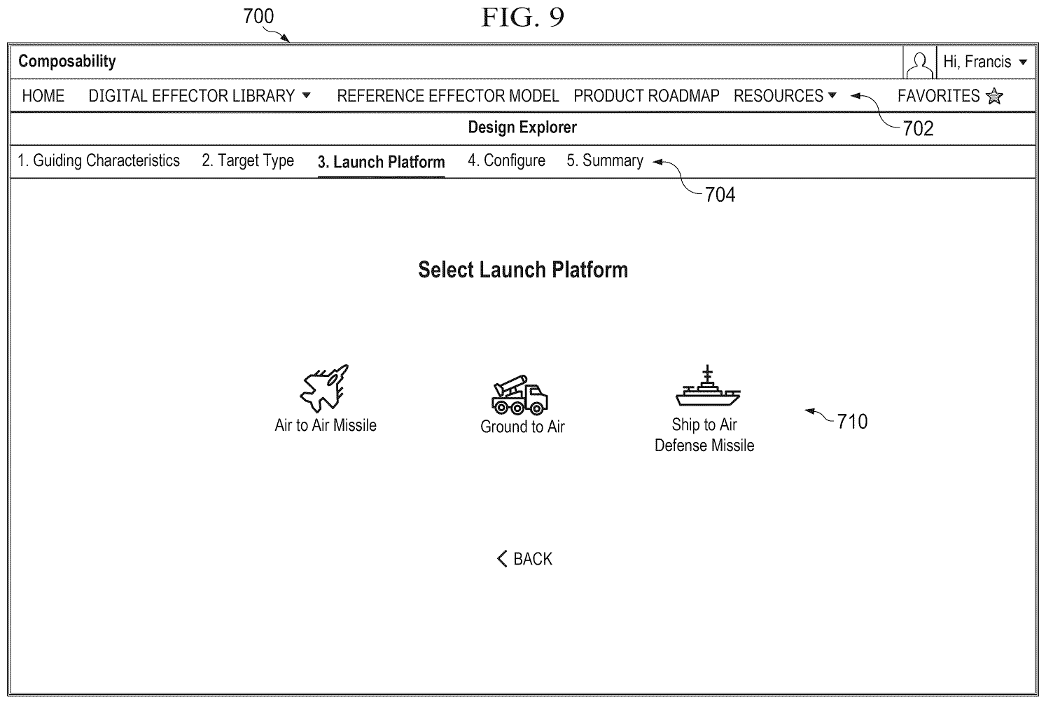

In this particular example, the questions further include a question 710 asking for an identification of the type of launch platform from which the effector being designed might be launched as shown in FIG. 9. In this example, the question 710 involves the user selecting one of multiple clickable icons to indicate whether the effector being designed will be launched as an air-to-air missile, as a ground-to-air missile, or as a ship-to-air missile. Here, the user may indicate a desire to design an effector to launched as a ground-to-air missile, which can represent yet another feature of the effector being designed.

Note that these specific questions 706-710 are examples only and that the design questions 302 can vary widely based (among other things) on the type of effector being designed. Also note that different selections by the user to one or more earlier questions can impact the number(s) or type(s) of subsequent questions asked and the options that are provided to the user as possible answers to the subsequent question(s).

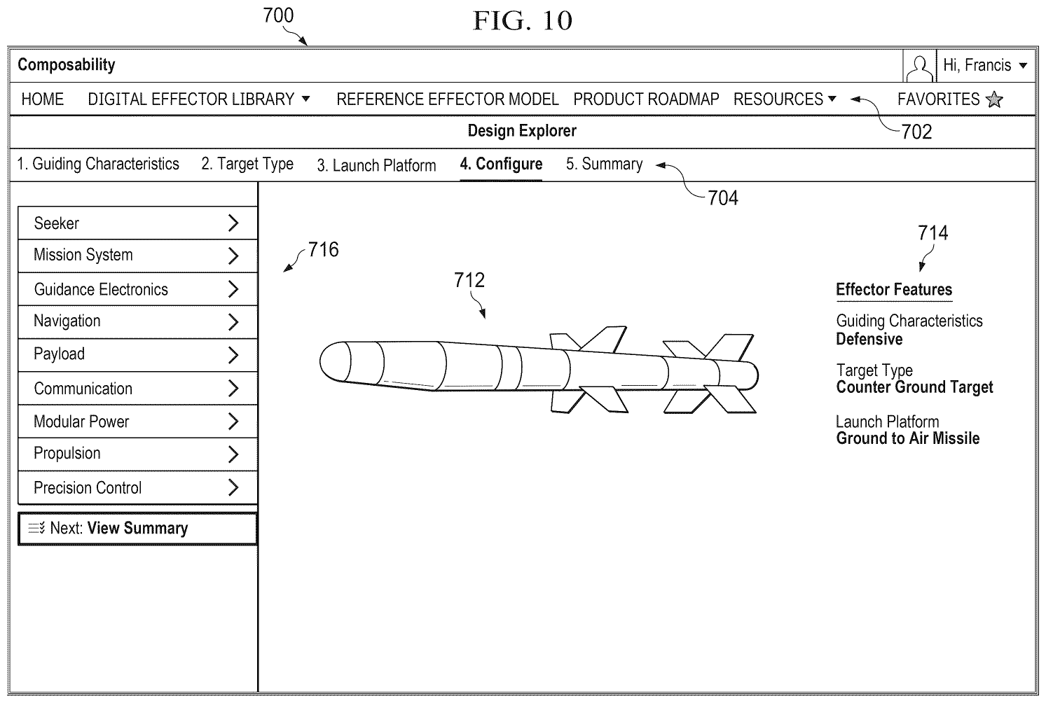

Once the questions 706-710 have been answered, the graphical user interface 700 can present an overview of the effector being designed as shown in FIG. 10. Here, the graphical user interface 700 includes a graphical representation 712 of the effector being designed, as well as a summary 714 of at least some of the features selected by the user via the questions 706-710. The graphical user interface 700 also provides a listing 716 of the various classes or categories of components and subsystems related to the effector being designed. As noted above, effectors may be associated with a number of component/subsystem classes or categories, which in this example includes seekers, mission systems, guidance electronics, navigation systems, payloads, communication systems, power systems, propulsion systems, and precision control systems. Note that other or additional component/subsystem categories may be used depending on the implementation and on the product being designed.

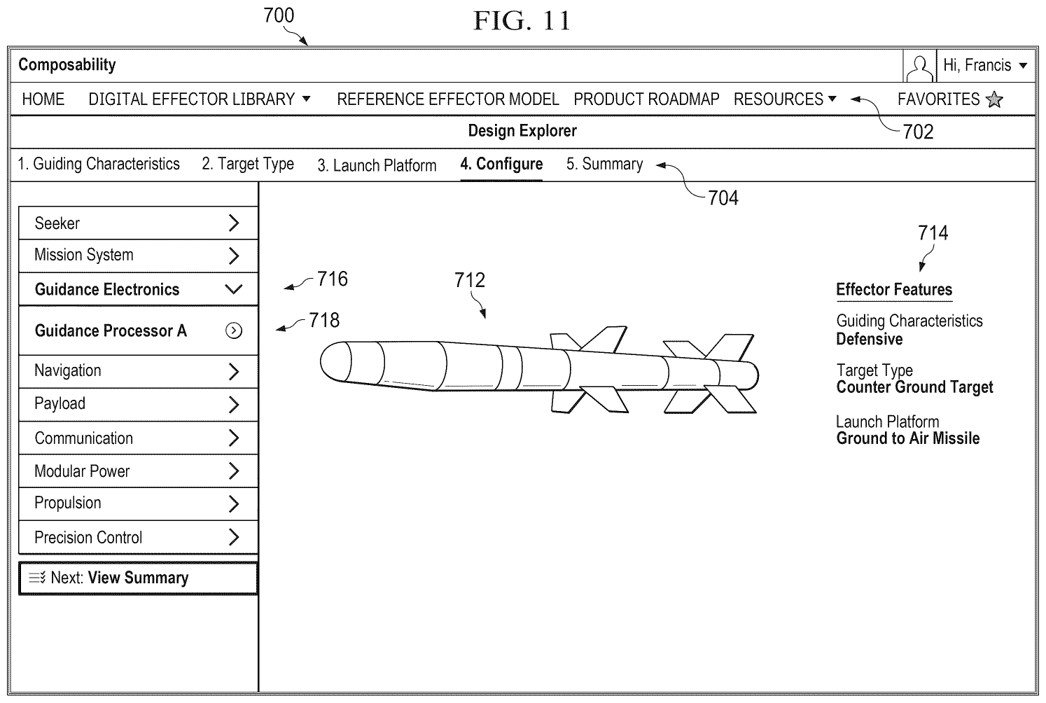

As shown in FIG. 11, each component/subsystem category in the listing 716 may be selected to reveal at least one particular component or subsystem 718 within that category. The specific components or subsystems 718 shown under each category in the listing 716 can be based on the user's answers to the questions 706-710. For instance, as described above, answers to the design questions 302 can be used to determine which components or subsystems 718 are suitable for use in the intended application as defined by the user using the feature profile definitions 308 and the digital library 310. In this example, there is a single component or subsystem 718 shown under the selected category in the listing 716, so that component or subsystem 718 can be automatically selected for use in the effector being designed. However, there may be multiple components or subsystems 718 under the selected category in the listing 716, in which case the user may be able to select a particular one of the components or subsystems 718 for use in the effector being designed. Note that the user may also be able to select each component or subsystem 718 in order to view additional information about that component or subsystem 718. Also note that the graphical representation 712 of the effector being designed may be updated as the user makes selections of components or subsystems 718 for use in the effector.

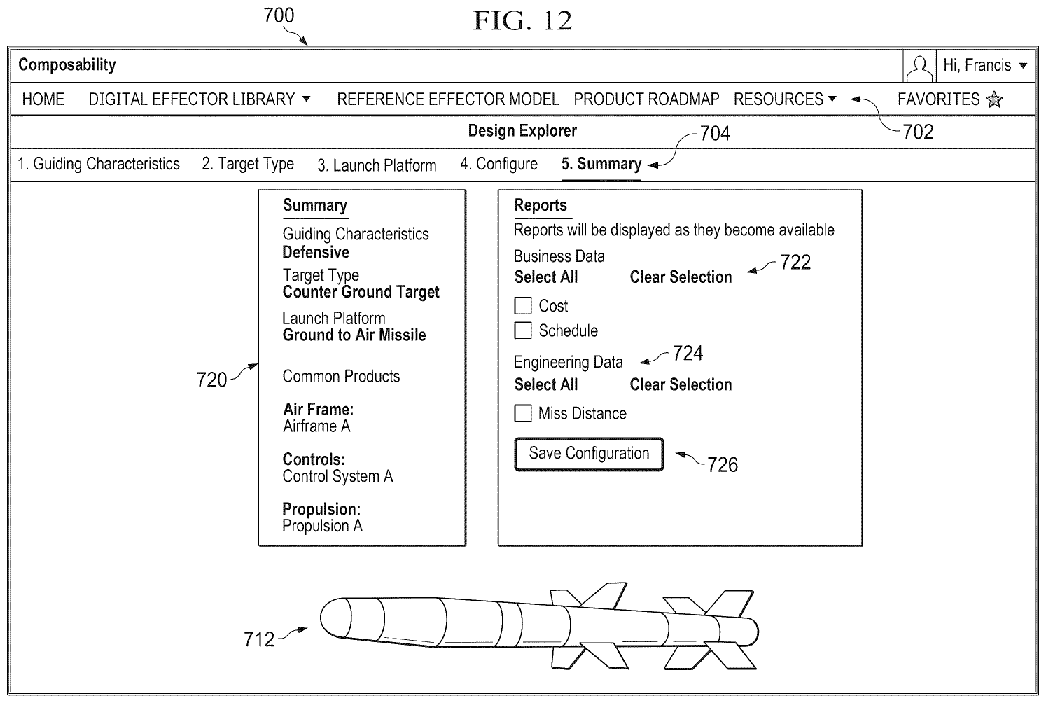

Once a suitable component or subsystem 718 under each category in the listing 716 is selected (either automatically or based on user input), the user can request to view a summary of the designed effector. An example of this is shown in FIG. 12, where the graphical user interface 700 includes the graphical representation 712 of the effector (possibly updated to include the components/subsystems selected for the effector). The graphical user interface 700 also includes a summary 720 identifying both (i) at least some of the features selected by the user via the questions 706-710 and (ii) at least some of the components/subsystems selected for the effector.

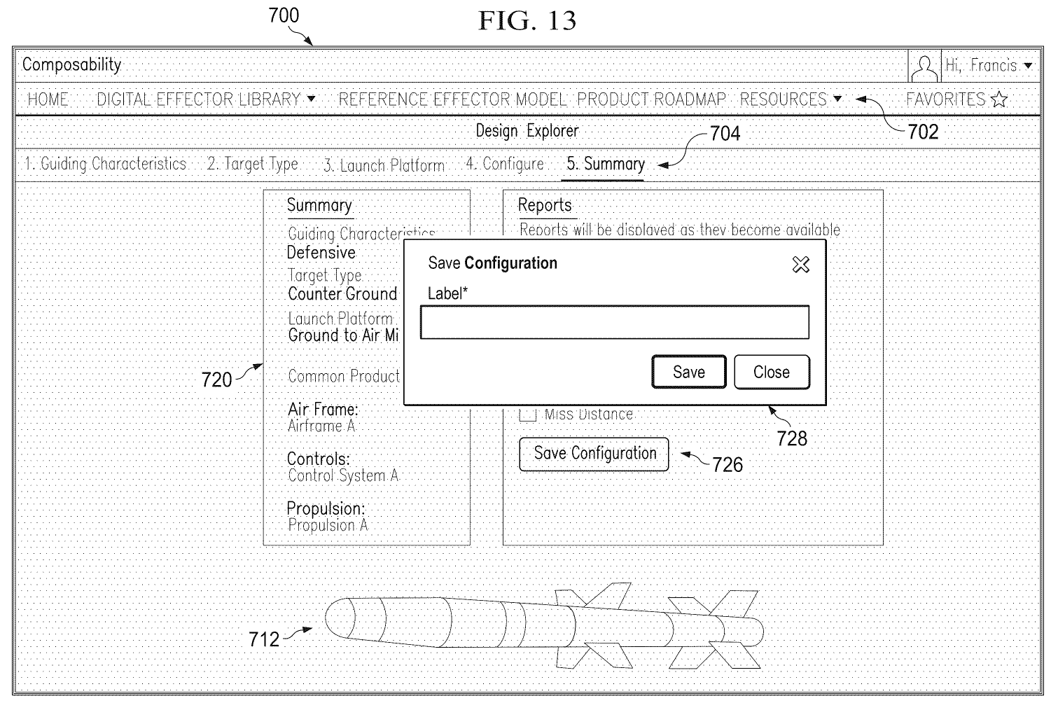

The user is also given the option of invoking various functions related to the effector being designed using controls 722-726. For example, one or more controls 722 may allow the user to initiate one or more business trade studies involving the effector, and one or more controls 724 may allow the user to initiate one or more engineering trade studies involving the effector. In this example, the one or more business trade studies can involve the cost of the effector and the production schedule of the effector, and the one or more engineering trade studies can involve an estimation of the “miss distance” of the effector. Miss distance refers to an average or other distance that the effector being designed is estimated to miss an intended target during use. The user may use the control 726 to save this particular configuration of the effector as a candidate product configuration 312. If the user elects to save this particular configuration, a pop-up window 728 as shown in FIG. 13 allows the user to provide a name for the product configuration and to save the product configuration.

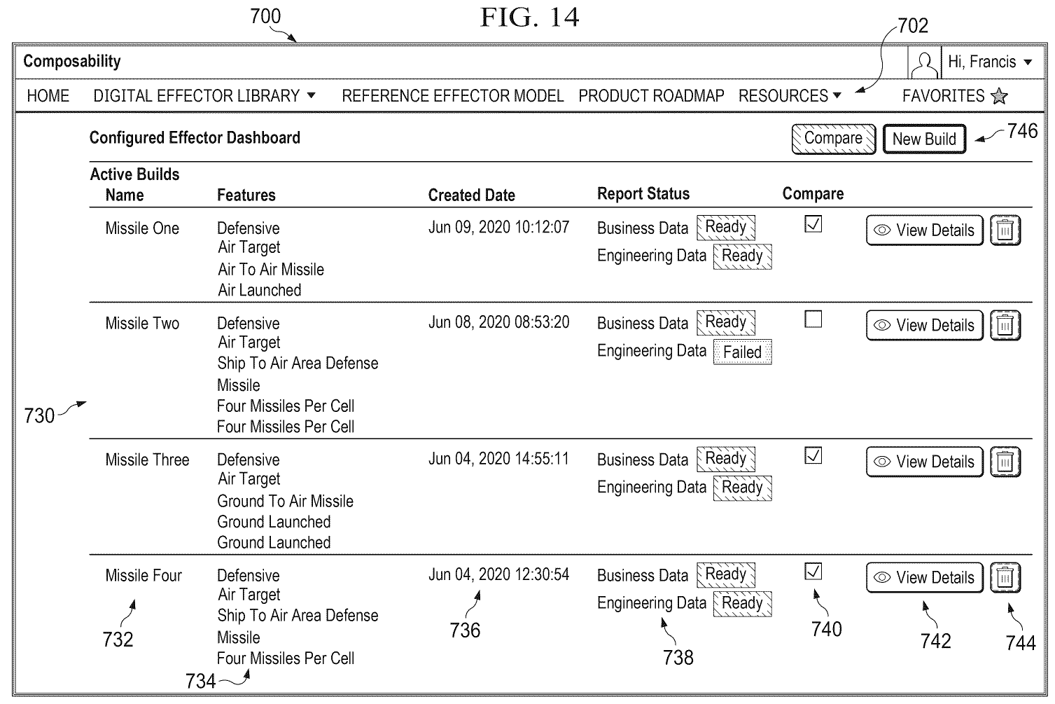

The graphical user interface 700 can also be used to present a dashboard display 730 to the user as shown in FIG. 14. The dashboard display 730 can summarize one or more candidate product configurations 312 that have been saved by the user or other users. In this example, the dashboard display 730 includes one or more entries, where each entry is associated with a different candidate product configuration 312. Here, each entry identifies a name 732 of the associated candidate product configuration 312, selected features 734 of the associated candidate product configuration 312, and a date 736 that the associated candidate product configuration 312 was created. Each entry also identifies a report status 738 for the associated candidate product configuration 312, where the report status 738 identifies the results of one or more trade studies or other analyses (such as those initiated via the controls 722-724). In this particular example, the report status 738 for the second entry indicates that the second listed effector design has failed an engineering trade study (such as when the miss distance simulation returns an excessively-large distance), while the other report statuses 738 indicate that the trade studies were successfully completed. Each entry further includes a checkbox 740 to allow for comparisons of selected effector designs, a control 742 allowing for a presentation of the specific details for the associated candidate product configuration 312, and a control 744 allowing for deletion of the associated candidate product configuration 312. Controls 746 can be used to initiate a comparison of any candidate product configurations 312 selected via their checkboxes 740 and to initiate a creation of a new candidate product configuration 312.

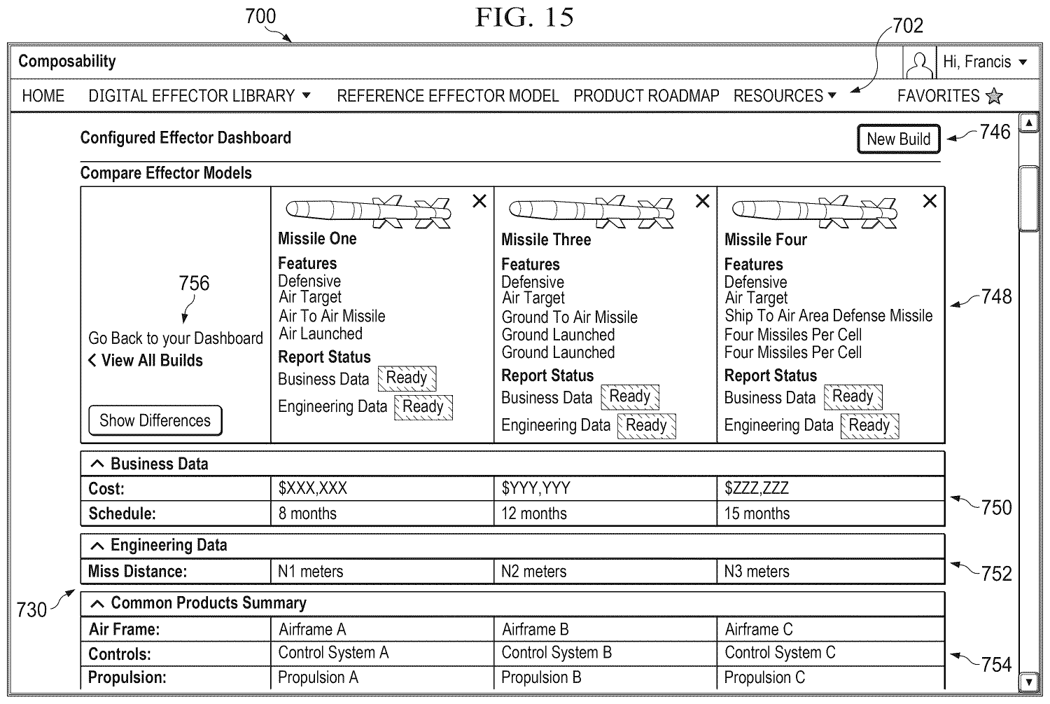

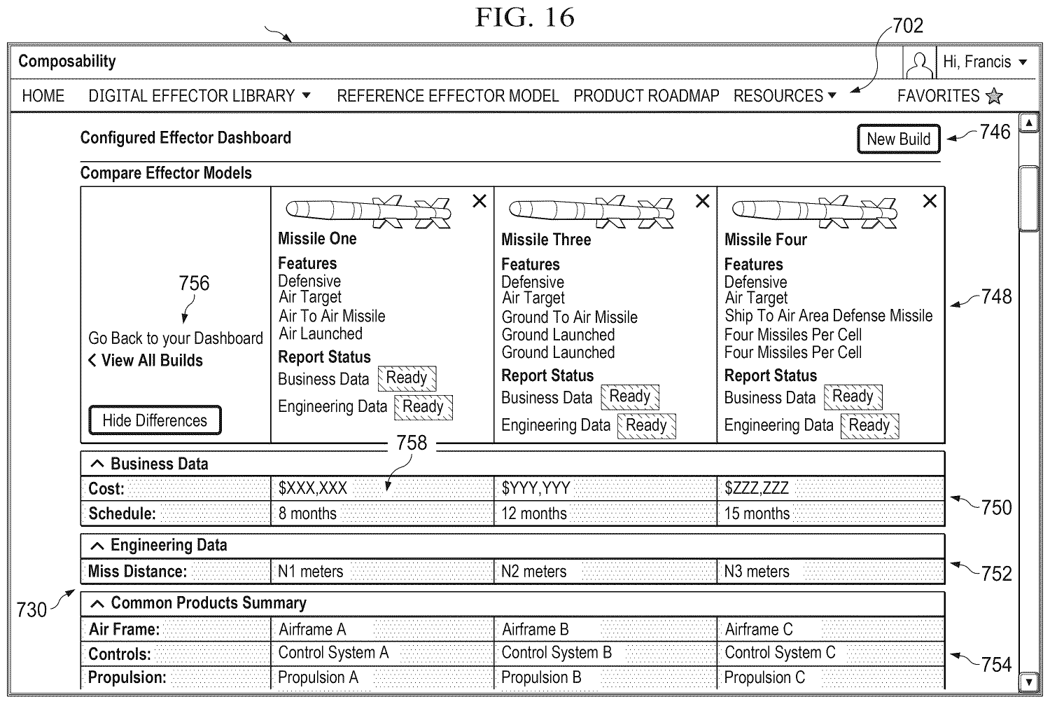

As shown in FIG. 15, the user has elected to compare multiple candidate product configurations 312 listed in the dashboard display 730, and the dashboard display 730 has been updated to include a comparison of the selected candidate product configurations 312. Here, the dashboard display 730 includes an identification 748 of the selected candidate product configurations 312, where each identification 748 includes a name and graphical representation of the associated candidate product configuration 312, features of the associated candidate product configuration 312, and one or more report statuses of the associated candidate product configurations 312. The dashboard display 730 also includes sections 750, 752, and 754 that respectively compare the results of the business trade studies, the results of the engineering trade studies, and the selected components/subsystems for the selected candidate product configurations 312. As shown in FIGS. 15 and 16, controls 756 can be used to return to the dashboard display 730 as shown in FIG. 14 or to show/hide differences between the information in the sections 750, 752, and 754. When the differences are hidden, the contents of the sections 750, 752, and 754 can be displayed normally as shown in FIG. 15. When the differences are shown, the contents of the sections 750, 752, and 754 can be displayed with highlighting or other indicators 758 to identify the entries in the sections 750, 752, and 754 for the selected candidate product configurations 312 that differ from one another.

Although FIGS. 7 through 16 illustrate one example of a graphical user interface 700 supporting a design explorer for composing products using common modular subsystems and components, various changes may be made to FIGS. 7 through 16. For example, the content, layout, and arrangement of the graphical user interface 700 are for illustration only and can vary as needed or desired. Also, while specific I/O mechanisms (such as clickable icons, lists, checkboxes, and buttons) are shown in the graphical user interface 700, any suitable I/O mechanisms may be used in the graphical user interface 700. In general, graphical user interfaces come in a wide variety of configurations, and FIGS. 7 through 16 do not limit this disclosure to any particular graphical user interface.

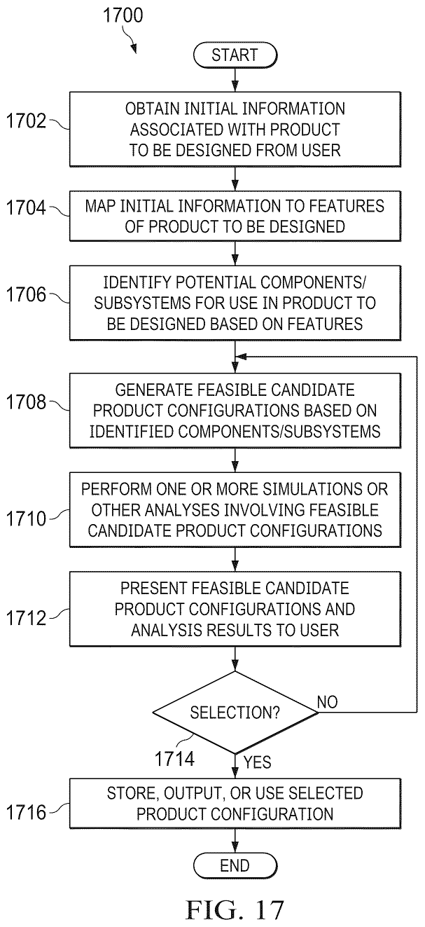

FIG. 17 illustrates an example method 1700 for using a design explorer for composing products using common modular subsystems and components according to this disclosure. For ease of explanation, the method 1700 is described as being performed by one or more application servers 106 interacting with one or more user devices 102a-102d in the system 100 of FIG. 1. However, the method 1700 shown in FIG. 17 may be performed using any suitable device(s) and in any suitable system(s).

As shown in FIG. 17, initial information associated with a product to be designed is obtained from a user at step 1702. This may include, for example, the processing device(s) 202 of the application server(s) 106 providing a graphical user interface 700 to a user 402 and obtaining answers to questions 302, 706-710 from the user 402 via the graphical user interface 700. The answers to the questions can be used (among other things) to identify an intended application for the product to be designed. The initial information is mapped to features of the product being designed at step 1704. This may include, for example, the processing device(s) 202 of the application server(s) 106 applying the feature model 304 to the initial information in order to map the user's answers to one or more features of the product being designed. Note, however, that one or more of the questions 302, 706-710 may be designed so that one or more of the answers themselves can be used as one or more features of the product being designed.

Potential components and subsystems that may be used in the product being designed are identified based on the features at step 1706. This may include, for example, the processing device(s) 202 of the application server(s) 106 using the feature profile definitions 308 to identify viable feature options for the different features of the product being designed, where the viable feature options are suitable for use in the intended application. This may also include the processing device(s) 202 of the application server(s) 106 using the digital library 310 to identify specific components and subsystems that are associated with those viable feature options. Feasible candidate product configurations are generated based on the identified components and subsystems at step 1708. This may include, for example, the processing device(s) 202 of the application server(s) 106 identifying different combinations of the identified components and subsystems that have been determined are usable in the intended application. The different combinations of the identified components and subsystems can form different feasible candidate product configurations 312. Note that, in some embodiments, one or more of the feasible candidate product configurations 312 may be generated using user input, such as via one or more user selections of one or more particular components or subsystems 718 identified in a listing 716 presented within the graphical user interface 700.

One or more simulations or other analyses involving the feasible candidate product configurations are performed at step 1710. This may include, for example, the processing device(s) 202 of the application server(s) 106 performing one or more business trade studies, one or more engineering trade studies, or one or more simulations using at least one suitable simulation model. One or more of the feasible candidate product configurations and optionally at least some of the analysis results or information based on the analysis results can be presented to the user at step 1712. This may include, for example, the processing device(s) 202 of the application server(s) 106 identifying one or more of the feasible candidate product configurations 312 in the graphical user interface 700, along with at least some of the analysis results or information summarizing or otherwise based on the analysis results, for presentation to the user 402. At this point, the user 402 may perform any desired actions, such as comparing multiple feasible candidate product configurations 312 and their associated simulation or other analysis results.

A determination is made whether the user selects a final feasible candidate product configuration at step 1714. This may include, for example, the processing device(s) 202 of the application server(s) 106 determining whether a particular feasible candidate product configuration 312 from among the identified feasible candidate product configurations 312 is selected by the user 402 for use. If so, the selected feasible candidate product configuration is stored, output, or used in some manner at step 1716. This may include, for example, the processing device(s) 202 of the application server(s) 106 treating the selected feasible candidate product configuration 312 as a final product configuration 330. This may also include the processing device(s) 202 of the application server(s) 106 storing the final product configuration 330 in a memory for later use or using the final product configuration 330 in any suitable manner, such as by forwarding the final product configuration 330 to one or more other users for approval or scheduling production of products based on the final product configuration 330. In general, the final product configuration 330 may be used in any suitable manner. If a final feasible candidate product configuration is not selected at step 1714, one or more earlier operations may be repeated in order to try and identify additional feasible candidate product configurations that might be acceptable to the user, thereby supporting an iterative approach to the generation of the feasible candidate product configurations 312. In some cases, one or more of the additional feasible candidate product configurations 312 may be generated based on updated or additional information provided by the user 402 or one or more other users.

Although FIG. 17 illustrates one example of a method 1700 for using a design explorer for composing products using common modular subsystems and components, various changes may be made to FIG. 17. For example, while shown as a series of steps, various steps in FIG. 17 may overlap, occur in parallel, occur in a different order, or occur any number of times.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive (HDD), a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
obtaining, using at least one processing device, initial information associated with a product to be designed, at least some of the initial information identifying an intended application for the product to be designed;
identifying, using the at least one processing device, multiple features associated with the product to be designed based on the initial information;
identifying, using the at least one processing device and for each of the multiple features, one or more feature options that are acceptable for use in the intended application;
identifying, using the at least one processing device and for each of the multiple features, one or more components or subsystems that are associated with the one or more acceptable feature options for that feature, at least some of the identified components or subsystems being reusable in multiple products;
generating, using the at least one processing device, multiple feasible candidate product configurations based on the identified components or subsystems, each feasible candidate product configuration representing a potential design for the product and being acceptable for use in the intended application;
performing, using the at least one processing device, one or more simulations or analyses associated with each of the feasible candidate product configurations, at least one of the one or more simulations or analyses estimating performance of each of the feasible candidate product configurations; and
generating, using the at least one processing device, a graphical user interface that identifies (i) one or more of the feasible candidate product configurations and (ii) one or more results associated with the one or more simulations or analyses or information based thereon.

2. The method of claim 1, wherein:
the initial information is obtained from a user; and
identifying the multiple features associated with the product to be designed comprises mapping the initial information to the multiple features using a feature model.

3. The method of claim 1, wherein identifying the one or more feature options for each feature comprises:
identifying a feature profile definition for each feature, the feature profile definition identifying all feature options available for that feature; and
disregarding at least one feature option in one or more of the feature profile definitions based on (i) the intended application or (ii) the initial information, one or more remaining feature options in each feature profile definition representing the one or more acceptable feature options for the associated feature.

4. The method of claim 1, wherein identifying the one or more components or subsystems for each feature comprises:
identifying, using a digital library of components and subsystems, one or more components or subsystems associated with each acceptable feature option for the associated feature.

5. The method of claim 1, wherein generating the multiple feasible candidate product configurations comprises:
generating at least one of the feasible candidate product configurations using user input received via the graphical user interface, the user input identifying one or more user-selected components or subsystems to be used in the at least one feasible candidate product configuration.

6. The method of claim 1, wherein performing the one or more simulations or analyses associated with each feasible candidate product configuration comprises performing at least one trade study involving the feasible candidate product configuration.

7. The method of claim 1, wherein the graphical user interface presents a graphical representation of the product to be designed along with a listing of multiple classes of components or subsystems, at least one of the classes containing two or more components or subsystems that are each usable in the product.

8. An apparatus comprising:
at least one processing device configured to:
obtain initial information associated with a product to be designed, at least some of the initial information identifying an intended application for the product to be designed;
identify multiple features associated with the product to be designed based on the initial information;
identify, for each of the multiple features, one or more feature options that are acceptable for use in the intended application;
identify, for each of the multiple features, one or more components or subsystems that are associated with the one or more acceptable feature options for that feature, at least some of the identified components or subsystems being reusable in multiple products;
generate multiple feasible candidate product configurations based on the identified components or subsystems, each feasible candidate product configuration representing a potential design for the product and being acceptable for use in the intended application;
perform one or more simulations or analyses associated with each of the feasible candidate product configurations, at least one of the one or more simulations or analyses estimating performance of each of the feasible candidate product configurations; and
generate a graphical user interface that identifies (i) one or more of the feasible candidate product configurations and (ii) one or more results associated with the one or more simulations or analyses or information based thereon.

9. The apparatus of claim 8, wherein:
the at least one processing device is configured to obtain the initial information from a user; and
to identify the multiple features associated with the product to be designed, the at least one processing device is configured to map the initial information to the multiple features using a feature model.

10. The apparatus of claim 8, wherein, to identify the one or more feature options for each feature, the at least one processing device is configured to:
identify a feature profile definition for each feature, the feature profile definition identifying all feature options available for that feature; and
disregard at least one feature option in one or more of the feature profile definitions based on (i) the intended application or (ii) the initial information, one or more remaining feature options in each feature profile definition representing the one or more acceptable feature options for the associated feature.

11. The apparatus of claim 8, wherein the at least one processing device is configured to identify one or more components or subsystems associated with each acceptable feature option for the associated feature using a digital library of components and subsystems.

12. The apparatus of claim 8, wherein the at least one processing device is configured to generate at least one of the feasible candidate product configurations using user input received via the graphical user interface, the user input identifying one or more user-selected components or subsystems to be used in the at least one feasible candidate product configuration.

13. The apparatus of claim 8, wherein, to perform the one or more simulations or analyses associated with each feasible candidate product configuration, the at least one processing device is configured to perform at least one trade study involving the feasible candidate product configuration.

14. The apparatus of claim 8, wherein the graphical user interface is configured to present a graphical representation of the product to be designed along with a listing of multiple classes of components or subsystems, at least one of the classes containing two or more components or subsystems that are each usable in the product.

15. A non-transitory computer readable medium containing instructions that when executed cause at least one processor to:
obtain initial information associated with a product to be designed, at least some of the initial information identifying an intended application for the product to be designed;
identify multiple features associated with the product to be designed based on the initial information;
identify, for each of the multiple features, one or more feature options that are acceptable for use in the intended application;
identify, for each of the multiple features, one or more components or subsystems that are associated with the one or more acceptable feature options for that feature, at least some of the identified components or subsystems being reusable in multiple products;
generate multiple feasible candidate product configurations based on the identified components or subsystems, each feasible candidate product configuration representing a potential design for the product and being acceptable for use in the intended application;
perform one or more simulations or analyses associated with each of the feasible candidate product configurations, at least one of the one or more simulations or analyses estimating performance of each of the feasible candidate product configurations; and
generate a graphical user interface that identifies (i) one or more of the feasible candidate product configurations and (ii) one or more results associated with the one or more simulations or analyses or information based thereon.

16. The non-transitory computer readable medium of claim 15, wherein:
the instructions that when executed cause the at least one processor to obtain the initial information comprise instructions that when executed cause the at least one processor to obtain the initial information from a user; and
the instructions that when executed cause the at least one processor to identify the multiple features associated with the product to be designed comprise instructions that when executed cause the at least one processor to map the initial information to the multiple features using a feature model.

17. The non-transitory computer readable medium of claim 15, wherein the instructions that when executed cause the at least one processor to identify the one or more feature options for each feature comprise instructions that when executed cause the at least one processor to:
identify a feature profile definition for each feature, the feature profile definition identifying all feature options available for that feature; and
disregard at least one feature option in one or more of the feature profile definitions based on (i) the intended application or (ii) the initial information, one or more remaining feature options in each feature profile definition representing the one or more acceptable feature options for the associated feature.

18. The non-transitory computer readable medium of claim 15, wherein the instructions that when executed cause the at least one processor to generate the multiple feasible candidate product configurations comprise:
instructions that when executed cause the at least one processor to generate at least one of the feasible candidate product configurations using user input received via the graphical user interface, the user input identifying one or more user-selected components or subsystems to be used in the at least one feasible candidate product configuration.

19. The non-transitory computer readable medium of claim 15, wherein the instructions that when executed cause the at least one processor to perform the one or more simulations or analyses associated with each feasible candidate product configuration comprise:
instructions that when executed cause the at least one processor to perform at least one trade study involving the feasible candidate product configuration.

20. The non-transitory computer readable medium of claim 15, wherein the graphical user interface is configured to present a graphical representation of the product to be designed along with a listing of multiple classes of components or subsystems, at least one of the classes containing two or more components or subsystems that are each usable in the product.
